(19) United States
(12) Patent Application Publication
(10) Pub. No.: US 2026/0251676 A1
(43) Pub. Date: Aug. 27, 2026

(54) METHOD OF ANALYZING A PROBE TIP DEFLECTION SIGNAL OF A SCANNING PROBE MICROSCOPY SYSTEM

(71) Applicant: Nearfield Instruments B.V., Rotterdam (NL)

(72) Inventors: Hamed SADEGHIAN MARNANI, Rotterdam (NL); Jakob VAN DE LAAR, Oosterhout (NL); Artem KHACHATURIANTS, Rotterdam (NL)

(21) Appl. No.: 19/163,057

(22) PCT Filed: Mar. 8, 2024
(86) PCT No.: PCT/NL2024/050116

§ 371 Date: Sep. 8, 2025

(30) Foreign Application Priority Data
Mar. 10, 2023 (NL) 2034317

(51) Int. Cl. G01Q 10/06; G01Q 60/38

(52) U.S. Cl. CPC G01Q 10/06; G01Q 60/38

(57) ABSTRACT

The invention is directed at a method of analyzing a probe tip deflection signal of a scanning probe microscopy system. The system comprises a probe head comprising a probe including a probe tip arranged on a cantilever, the probe head being configured for scanning the probe tip along one or more directions parallel to a substrate surface. The probe head includes an actuator for applying a periodic motion to the probe, and a tip position detector provides a probe tip deflection signal indicative of a deviation of the probe tip from a reference position. The method comprises obtaining at a scan position a plurality of samples of the probe tip deflection signal over time for providing a signal profile, and identifying the signal profile to be associated with a grazing impact of the probe tip on the sidewall. A location coordinate of a sidewall structure is provided by an obtained z-position.

### FIELD OF THE INVENTION

The present invention is directed at a method of analyzing a probe tip deflection signal of a scanning probe microscopy system, wherein the system comprises at least one probe head comprising a probe including a probe tip arranged on a cantilever, the probe head being configured for scanning the probe tip along one or more directions parallel to the substrate surface, the probe head comprising an actuator for applying a periodic motion to the probe tip during said scanning, and a tip position detector for providing a probe tip deflection signal indicative of a deviation of an actual position of the probe tip from a reference position along a z-direction transverse to the substrate surface, the method comprising obtaining, at a first scan position on the substrate surface, a first plurality of samples of the probe tip deflection signal over time at one or more positions of the probe tip along the z-direction during at least one first cycle of the periodic motion, for providing a signal profile at the first scan position using the first plurality of samples.

### BACKGROUND

Scanning probe microscopy (SPM) is an imaging technology that enables to provide images of on-surface and sub-surface structures at nanometer scale. The technology is non-optical and therefor is not diffraction limited, and as a result may for example be applied in semiconductor manufacturing processes, where structures of integrated circuits become so small that, due to being diffraction limited, optical imaging no longer suffices. Scanning probe microscopy, however, is likewise applied in other situations as a good alternative to optical imaging or scanning electron microscopy (SEM).

Scanning probe microscopy operates on the basis of a probe, having a cantilever and a probe tip (typically at the end of the cantilever), wherein the probe tip moves relative to a surface of a substrate while continuously or intermittently making contact therewith. With ‘contact’, it is meant here that the probe tip is brought at least in such a proximity to the surface that influence thereof is noticeable in the transfer function of the probe's dynamic behavior or static response/behavior. SPM is performed in various different modes, the most common modes being contact, intermittent contact and non-contact mode. In contact mode, the probe tip is kept in contact with the surface during scanning. If a structure on the surface is encountered, the probe tip is forced upward (e.g. a block) or falls downward (e.g. a trench). This change in probe tip deflection can be compensated in feedback, which enables to accurately determine the height or depth of the structure. In intermittent contact mode, the probe vibrates above the surface at a frequency well below the first resonance frequency and intermittently touches the surface. A difference in deflection amplitude is thereby indicative of a change in height or depth, which as well can be measured accurately using a compensating feedback loop that re-establishes the original minimum (or maximum). In non-contact mode, the probe tip is moved in very close proximity such as to encounter the influence of the surface onto the dynamic behavior of the probe.

The above shortly describes on-surface measurements, also referred to as surface topography measurements. For subsurface measurements, an ultrasonic vibration may further be applied to the probe or the sample or both, and the presence of subsurface features may be detectable in resulting waves measurable at the surface or from changes in the contact stiffness, which also allows imaging thereof.

Although SPM as described above provides outstanding performances when it comes to highly accurate imaging of structures on and in samples and substrates down to nanometer scale, the characterization of high aspect ratio features (i.e. features having relatively steep and high walls and structure parts) is more difficult. Various measurement techniques, using SPM, have been developed in order to perform such measurements. However, a further hurdle in this connection is the correct characterization and measurement of sidewall structures, i.e. structures that are present on or extend into the sidewall of a regular surface feature. As the structures required to be produced for the manufacturing of modern semiconductor devices become more complex, the need for a manner to correctly characterize these sidewall features will grow.

### SUMMARY OF THE INVENTION

It is an object of the present invention to provide a method of analyzing a probe tip deflection signal of a scanning probe microscopy system, which enables to characterize a sidewall structure present on or in a sidewall of a surface feature, the surface feature being present on a surface of a substrate.

To this end, there is provided herewith a method of analyzing a probe tip deflection signal of a scanning probe microscopy system, for determining a location coordinate of a sidewall structure present on or in a sidewall of a surface feature, the surface feature being present on a surface of a substrate. The scanning probe microscopy system comprises at least one probe head, which comprises a probe including a probe tip arranged on a cantilever. The system may include a single probe head, but may likewise include multiple probe heads. These probe heads may be independently movable with respect to each other, for example in a specific embodiment a system may comprise a collection of probe heads that can be independently positioned at various places with respect to the substrate surface such as to enable simultaneous and parallel scanning of multiple areas on the surface. A more basic embodiment, though, may comprise only a single probe head that is movably connected to another system part, e.g. a metrology frame or another structure of the system. The at least one probe head is configured for scanning the probe tip along one or more directions parallel to the substrate surface. For example these may be orthogonal directions across the surface and the scanning may be performed such as to scan an area of the surface. The probe head comprises an actuator for applying a periodic motion to the probe (tip) during said scanning, and a tip position detector for providing a probe tip deflection signal indicative of a deviation of an actual position of the probe tip from a reference position along a z-direction transverse to the substrate surface. For example, the skilled person will be aware of various tip position detectors that may be applied, such as an optical beam detector (OBD) arrangement or a piezoresistive sensor.

The method in accordance with the present invention comprises the following steps. At a first scan position on the substrate surface, a first plurality of samples of the probe tip deflection signal is obtained over time at one or more positions of the probe tip along the z-direction, during at least one first cycle of the periodic motion. This is performed in order to provide a signal profile at the first scan position, which is based on or is created using the first plurality of samples. As stated, the first plurality of samples is obtained during at least one first cycle of the periodic motion, thus in order to obtain the signal profile of the signal during this at least one cycle. The signal profile during at least a part of the cycle provides the desired data for the method, and also enables to characterize the signal profile in other steps. The method further includes the step of identifying the signal profile to be associated with a grazing impact of the probe tip on the sidewall. This characterization and identification step can be performed based on sufficient data being gathered during the at least one cycle (e.g. Force-Distance Curve (FDC)), as described above. Further to this, please note that the term grazing impact here refers to the probe tip grazing past the sidewall, while lightly being in contact therewith. Alternatively this type of motion may also be referred to as sliding impact or sliding motion, i.e. the probe tip sliding over the side wall while moving downward (or upward or both, dependent on the set-up of the system) towards the base thereof.

The method furthermore includes a step of detecting, in a slope or shape of the signal profile which is associated with a probe tip motion in a z-direction towards the substrate surface, one or more variations in the slope or shape. In other words, while moving towards the substrate surface e.g. in a downward motion towards the bottom of a trench or while sliding over the sidewall of the surface feature, the probe tip may encounter obstructions. These obstructions for example may be formed by the sidewall structures. For example, a hole or opening in the sidewall may catch the probe tip in its motion towards the base of the sidewall. This may temporarily stop the motion of the probe tip, while the remainder of the probe including the cantilever, under the influence of the translating motion exerted by the z-actuator, continues to be forced to proceed its motion. The probe will therefore bend, and this is directly visible as a ripple or variation in the slope of the probe tip deflection signal. At some time after being caught, the probe tip will break loose and continue its motion. In that case the velocity receives an additional push by the biased cantilever, which results in a higher than average velocity. Similarly, a positive structure (i.e. a structure extending out of the sidewall) will likewise catch the probe tip and result in a deflection.

The variations identified in the probe tip deflection signal can be analyzed in order to derive the z-position of where these occurred. These z-positions may be considered an estimate of the z-position of the structure. The method, therefore, may further comprise a step of associating at least one of the variations with an interaction between the probe tip and the sidewall structure during the probe tip motion, and obtaining a z-position of the probe tip at the at least one variation. Thereafter, the method includes to provide, as the location coordinate of the sidewall structure, the obtained z-position at the at least one variation.

The claimed invention, as described above, provides the advantage of providing an elegant manner to detect the presence of sidewall features, and of providing a manner to estimate their z-positions. This is an important advantage, because the detection, sensing and inspection of sidewall features with their real z-positions, cannot be achieved with conventional ways of performing scanning probe microscopy. The invention uses the grazing impact of the probe tip on the sidewall, and the principle of the probe tip being caught by the sidewall structures, to identify the presence of sidewall structures and to provide an estimate of the z-position.

In some embodiments of the invention, the one or more variations relate to one or more of: ripples in the (slope of) the signal profile; or local extremes in the slope of the signal profile, such as local maxima or local minima. As explained, variations in the probe tip velocity in its periodic motion cycle will be visible as ripples on the slope of the signal. In some situations, the presence of a sidewall structure extending on or in the sidewall will briefly slow down (but not completely stop) the probe tip motion during its sliding, and after passing the obstruction the probe tip will accelerate to catch up with the cantilever, similar to a leaf spring being released. In these situations, which may for example occur with the encountering of a small structure (e.g. a dimple, indentation or scratch), the variation will be visible as a ripple on the slope, but mostly in absence of real local minima or maxima due to the fact that the probe tip velocity remains non-zero during the event. In some situations, however, for example upon encountering an opening or hole in the sidewall, the probe tip may accelerate due to being released into the opening, after which it may be stopped by being caught and held by the opposing wall of the opening. In the deflection signal, a deceleration will result in an increase of deflection (probe bends back), whereas an acceleration of the probe tip will result in a decrease of deflection (probe returns to equilibrium or continues to bend forward)—note though that “increase” and “decrease” depend on the used sign conventions and that bending back and forth accurately describe what physically occurs. Therefore, upon encountering an opening, local extremes such as local minima or maxima are formed upon the probe tip being released into the opening or being stopped on the other side thereof. In yet other situations, a sidewall structure that positively extends from the sidewall will obstruct the probe tip during its grazing impact, and thus will cause the probe tip to stop and the probe to bend back. Upon release, dependent on when this happens, the probe tip may accelerate at once to the base of the sidewall, e.g. at the bottom of a trench. The variations may well be analyzed in order to determine each step in the dynamic behaviour of the probe during the grazing impact or sliding motion past the sidewall.

In some embodiments, the step of identifying the signal profile to be associated with a grazing impact comprises providing the signal profile to a pattern recognition algorithm or pattern recognition data model for performing the identification. In other or further embodiments, the step of identifying the signal profile to be associated with a grazing impact comprises comparing the signal profile to one or more reference profiles. The signal profile of a probe tip in sliding motion (grazing impact) past a sidewall, distinguishes from a regular motion of a probe tip that freely approaches a surface. The recognition of this signal profile of the deflection signal may thus be automated, e.g. in the above manner, such that an automated inspection of the metrics of sidewall structures becomes a potential application of the method and system of the invention. Automated recognition of the signal profile may be achieved based on other specifics of the signal.

In other or further embodiments, the one or more sidewall structures include at least one of: a structure extending from the sidewall, or an opening or an indentation extending into the side wall. This has been discussed above, the invention is not limited to a specific type of sidewall structures.

In other or further embodiments, the step of detecting one or more variations includes detecting a plurality of variations, and wherein the step of associating includes: associating at least a first variation with an interaction between the probe tip and a first sidewall structure, associating at least a second variation with an interaction between the probe tip and a second sidewall structure, obtaining a first z-position of the probe tip at the first variation and obtaining a second z-position of the probe tip at the second variation, for associating the first and the second z-position with the first and the second sidewall structure. The method of the present invention may be applied in order to identify and determine the location coordinates of a plurality of sidewall structures that may be present on or in a sidewall of a surface feature. For example, a surface feature may comprise a sidewall on which multiple structures at different z-positions may be present, and the present method may be applied to identify and determine the z-positions of all of these structures.

In some embodiments, the one or more sidewall structures include at least one opening or indentation extending into the sidewall of the surface feature, wherein the method further comprises: obtaining, at a second scan position and during at least one second cycle of the periodic motion, a second plurality of samples of the probe tip deflection signal over time, wherein the second scan position coincides with a top surface of the surface feature; wherein during the second cycle, an acoustic signal is applied to at least one of the substrate or the probe tip such as to perform a subsurface feature detection measurement at the second scan position. In this particularly advantageous class of embodiments, the method of the present invention is combined with subsurface scanning probe microscopy. The major advantage achievable therewith is that the method of the present invention enables to determine the z-positions of sidewall structures, such as an opening in a sidewall at a certain z-level, whereas the present class of embodiments enables to measure the depth of such an opening or the shape thereof by performing subsurface measurements underneath the top surface of the surface feature. Therefore, in some of these embodiments, the method for example further comprises analyzing the second plurality of samples of the probe tip deflection signal (during which the acoustic signal is applied) such as to obtain measurement data indicative of a depth of the opening or indentation extending into the sidewall. The idea in this embodiment is to use the subsurface signal for obtaining this measurement data indicative of the depth of the opening or indentation extending into the sidewall.

In other or further embodiments, the reference position is an equilibrium position, wherein the equilibrium position is a position which is in use assumed by the probe tip in absence of a force exerted thereon and in absence of the periodic motion. In principle, any other position may be used as reference position, however the use of the equilibrium position as reference position enables accurate calibration of the instrument.

In other or further embodiments, the surface feature relates to a fin structure of a semiconductor element which is present on or is being formed on the surface, wherein the fin structure extends in a first direction along the substrate surface, wherein the method comprises a step of scanning the probe tip relative to the surface in a scanning direction, such that the scanning direction is parallel to the first direction. Aligning the scanning direction to the direction of the fin structure, eases up the task of establishing grazing impact of the probe tip on the sidewall. Furthermore, the grazing impact can be established over a range of adjacent positions along the scanning direction in case the scanning direction is aligned with the fin structure. In substrates wherein a plurality of parallel fins is present, many or each of these having sidewall structures, the z-positions of these sidewall structures may conveniently be verified in a plurality of locations across the surface for a number of these fins.

In accordance with a second aspect thereof, the invention is directed at a method of operating a scanning probe microscopy system such as to perform a method in accordance with the invention according to the first aspect, analyzing a probe tip deflection signal of a scanning probe microscopy system, for determining a location coordinate of a sidewall structure present on or in a sidewall of a surface feature, the surface feature being present on a surface of a substrate, wherein the system comprises at least one probe head comprising a probe including a probe tip arranged on a cantilever, the probe head being configured for scanning the probe tip along one or more directions parallel to the substrate surface, the probe head comprising an actuator for applying a periodic motion to the probe (tip) during said scanning, and a tip position detector for providing a probe tip deflection signal indicative of a deviation of an actual position of the probe tip from a reference position along a z-direction transverse to the substrate surface, wherein the scanning probe microscopy system further comprises a controller and a memory, the memory being configured for storing instructions which when loaded cause the controller to perform the steps of: controlling the system such as to scan the probe tip relative to the substrate surface; obtaining, at a first scan position on the substrate surface, a first plurality of samples of the probe tip deflection signal over time at one or more positions of the probe tip along the z-direction during at least one first cycle of the periodic motion, for providing a signal profile at the first scan position using the first plurality of samples; identifying the signal profile to be associated with a grazing impact of the probe tip on the sidewall; detecting, in a slope of the signal profile which is associated with a probe tip motion in a z-direction towards the substrate surface, one or more variations in the slope or shape; and associating at least one of the variations with an interaction between the probe tip and the sidewall structure during the probe tip motion, and obtaining a z-position of the probe tip at the at least one variation; providing, as the location coordinate of the sidewall structure, the obtained z-position at the at least one variation.

Furthermore, in accordance with a third aspect thereof, the invention is directed at a computer program product embodied on a distribution medium readable by a computing device and comprising program instructions which, when loaded into a scanning probe microscopy system, execute the method according to the first or the second aspect.

### BRIEF DESCRIPTION OF THE DRAWINGS

The invention will further be elucidated by description of some specific embodiments thereof, making reference to the attached drawings. The detailed description provides examples of possible implementations of the invention, but is not to be regarded as describing the only embodiments falling under the scope. The scope of the invention is defined in the claims, and the description is to be regarded as illustrative without being restrictive on the invention. In the drawings:

FIG. 1 schematically illustrates various exemplary three dimensional structures of semiconductor elements;

FIGS. 2A and 2B show an image of a cross section of a three dimensional structure of a fin FET and a schematic drawing thereof;

FIG. 3 shows a scanning probe microscopy device for use in a method in accordance with the present invention;

FIG. 4 schematically illustrates the method of the invention in accordance with some embodiments thereof;

FIG. 5 illustrates a probe tip deflection signal including a plurality of periodic motion cycles;

FIG. 6 illustrates a part of the probe tip deflection signal of FIG. 5 as useable in a method in accordance with the present invention;

FIG. 7 schematically illustrates a method in accordance with some embodiments of the present invention;

FIG. 8 schematically illustrates the principle of a method in accordance with the present invention for a sidewall with multiple openings or recesses therein;

FIG. 9 schematically illustrates the principle of a method in accordance with the present invention for a sidewall with an opening or recess therein;

FIG. 10 schematically illustrates the principle of a method in accordance with the present invention for a sidewall with an indentation;

FIG. 11 schematically illustrates the principle of a method in accordance with the present invention for a sidewall with a sidewall structure extending thereon.

### DETAILED DESCRIPTION

Terminology used for describing particular embodiments is not intended to be limiting of the invention. As used herein, the singular forms “a”, “an” and “the” are intended to include the plural forms as well, unless the context clearly indicates otherwise. The term “and/or” includes any and all combinations of one or more of the associated listed items. It will be understood that the terms “comprises” and/or “comprising” specify the presence of stated features but do not preclude the presence or addition of one or more other features. It will be further understood that when a particular step of a method is referred to as subsequent to another step, it can directly follow said other step or one or more intermediate steps may be carried out before carrying out the particular step, unless specified otherwise. Likewise it will be understood that when a connection between structures or components is described, this connection may be established directly or through intermediate structures or components unless specified otherwise.

The invention is described more fully hereinafter with reference to the accompanying drawings, in which embodiments of the invention are shown. In the drawings, the absolute and relative sizes of systems, components, layers, and regions may be exaggerated for clarity. Embodiments may be described with reference to schematic and/or cross-section illustrations of possibly idealized embodiments and intermediate structures of the invention. In the description and drawings, like numbers refer to like elements throughout. Relative terms as well as derivatives thereof should be construed to refer to the orientation as then described or as shown in the drawing under discussion. These relative terms are for convenience of description and do not require that the system be constructed or operated in a particular orientation unless stated otherwise.

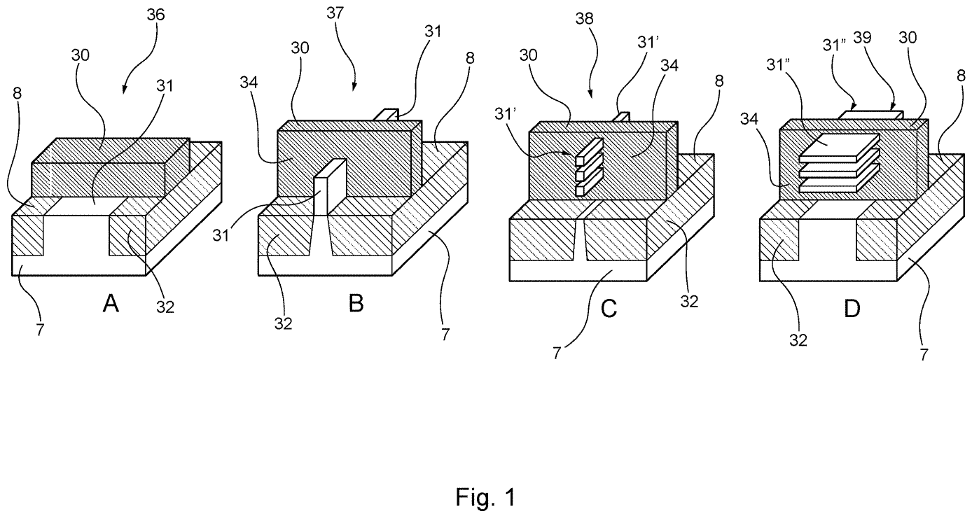

FIG. 1 schematically illustrates various exemplary three dimensional structures 30 of semiconductor elements that may be present on the surface 8 of a substrate 7. In element A on the left side of FIG. 1, a normal field effect transistor (FET) is illustrated. The FET 36 includes a gate 30 provided as a structure on the surface 8 of a substrate 7. Underneath the gate 30 a silicon source and drain structure 31 extends below the surface 8. The gate 30 enables to control the conductivity of the area underneath the gate 30 in the source/drain structure 31.

To the right of device A, device B illustrates a finFET 37. The finFET 37 comprises a gate structure 30 through which the source and drain structure 31 extends. The gate 30 is therefore present on three sides of the source and drain structure 31, such that a much better control of the conductivity within the source and drain 31 is obtained. Reference numeral 34 indicates the sidewall of the gate structure 30. In element C to the right of element B, the substrate 7 includes a gate-all-around nanowire structure. The gate-all-around nanowire structure comprises a gate 30 having a side wall 34. Through the gate 30, a number of nanowires 31′ extends all the way through the gate 30. The nanowires 31′ provide the source and drain of the gate all around field effect transistor. It may be appreciated, by means of a nanowire, the gate 30 is present on all sides of the nanowires 31′, and thereby gives right to the naming gate-all-around.

Another gate-all-around structure is provided by element D in FIG. 1, to the right side thereof. In element D, the gate-all-around device comprises a plurality of lobes 31″ that extend through the gate 30 forming the source and drain thereof.

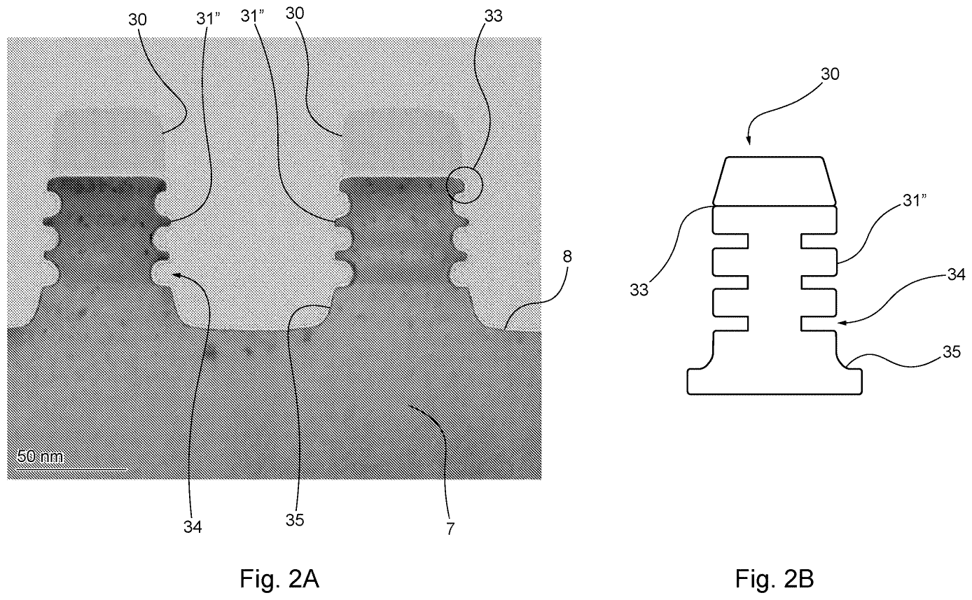

The cross-section of element 39 is illustrated in FIG. 2B, and an image thereof is provided in FIG. 2A. The image shows the gate 30 in cross-section, including the sidewall structure 31′ extending from the sidewall 34. The base of the trenches formed between the structure 30 is designated with reference numeral 35. In fact, the sidewall structures 31″ extend from the sidewall 34, but in cross-section one can also say that the sidewall structures 31″ are formed by recesses between the lobes 31″. Furthermore, the interface 33 provides the interface between the gate 30 and the first source/drain structure 31″.

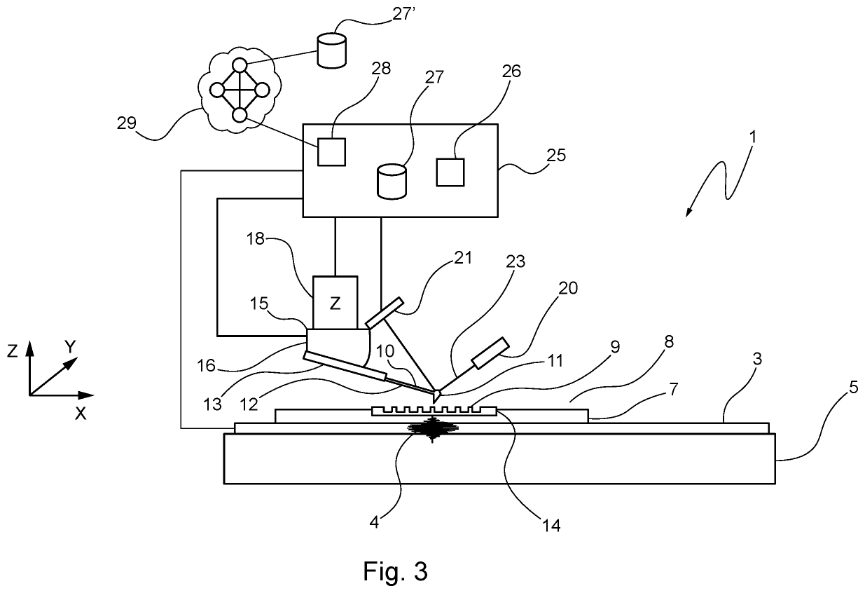

FIG. 3 schematically illustrates a scanning probe microscopy (SPM) system 1. The system 1 is suitable to be used in a method in accordance with the present invention. For example, the system 1 includes a processing device 26 and a memory 27 and/or 27′ which are suitable for storing instructions which, when executed by the processing device 26, cause the processing device 26 to carry out a method as described herein, in accordance with one or more embodiments of the invention. The processing device 26 in FIG. 3 is illustrated as a single entity in the SPM system 1. However, the skilled person may appreciate that although all the described method steps may be implemented by using a single processing device 26, the processing device 26 may be implemented by using multiple elements that together perform the described method steps. The processing device 26 may thus comprise a cluster of multiple processing devices, or may be implemented by various entities which individually perform certain (partial) steps and which cooperatively implement the invention. Furthermore, as illustrated, the memory 27 may be an internal memory 27 or may be an external memory 27′ or another external entity reachable via a data communication network 29. To communicate with data communication network 29, the system 1 may comprise a communication unit 28. In FIG. 3, the data storage elements 27, data processing elements 26 and data communication elements 28 are all illustrated as being part of analyzer unit 25 of the system 1. Although this may in many cases be implemented in this manner, this may not always be the case (as already suggested above). The illustration of a single entity 25 in FIG. 3 is for the sole purpose of not unnecessarily complicating the figures.

In the figures, elements that are technical and functional equivalents, i.e. performing a same or similar function in a same or similar manner with respect to the invention as described herein, may be designated by a same reference numeral or by a same reference numeral followed by a prime (′) or a sub-numbering (“-1”, “-2”, . . . ). These entities, such as data repositories 27 and 27′, may be of a same nature, of a different technical nature or may be implemented (e.g. connected or controlled) in a different manner, while in terms of the invention both providing the function of enabling the storing of data or operation instructions for the processing device 26. The memory 27′ in FIG. 3, has been designated including prime (′) in order to indicate that although this element performs (or is able to perform) a function similar or even in certain embodiments identical to the internal memory 27 of system 1′, this memory 27′ (which may even be implemented as a server or as an externally stored data file or data base) is different in the sense that it is not an internal memory but an external memory, without departing from its function in the embodiments of the present invention. The above is just an example, and may apply likewise to other entities described below. In principle, unless the contrary is specifically indicated in any part of the present document, it is to be assumed that any entity or element described may be implemented in a different manner in an alternative embodiment. The embodiments described or illustrated are not to be considered as limiting on the invention, which is only restricted by the appended claims defining the scope and spirit of the invention.

In the system 1 of FIG. 3, a substrate carrier 3 is configured for supporting the substrate or sample 7 to be examined by the SPM system 1. The substrate carrier 3 is configured, by comprising or being connected to actuators (not shown), for moving the substrate 7 in a plane parallel to the carrier 3. This is typically referred to as the XY-plane of the system. Apart from the ability to move the substrate 7 in the X- and Y-directions, the substrate carrier 3 is connected to a metrology frame 5 which provides a fixed base to the system. The SPM system 1 further includes one or more scan heads 15 which are movable in the Z direction. The scan heads 15 each include a chip holder 16 enabling to hold a probe chip 13 comprising a probe 10 forming the sensing element of the SPM system 1. The probe 10 includes a cantilever 12 and probe tip 11. The probe tip 11, typically includes a very sharp tip that allows to very accurately (with nanometer accuracy) scan and take measurements at the surface 8 of a substrate 7.

In addition to the above, typically the scan head 15 further include a sensor system for determining the exact position of the cantilever relative to the scan head. For example, the sensing system in FIG. 3 consists of an optical beam deflection (OBD) unit provided by a laser unit 20 for generating an optical beam 23, and a four quadrant optical sensor 21 that receives the reflected beam 23. The beam 23 is directed by the optical system to the backside of the probe cantilever 12, which includes a specular reflective surface. The specular reflective surface of the probe cantilever 12 reflects the beam 23 onto the optical detector 21. Any displacement of the probe tip 11 results in the location of impact of the beam 23 on the optical detector 21 to displace as well. In a four quadrant optical detector 21, the light spot formed by beam 23 preferably by default is set to be located exactly in the middle of the four different quadrants of the detector. Therefore, an equal part of the light spot falls on to each quadrant of the four quadrant optical detector 21. It may be appreciated that, even if in practice the laser beam 23 would not exactly be aligned in this manner, the principle of detecting a displacement of the light spot will be the same. All that is needed in order to detect a displacement is that each of the four quadrants of the optical detector 21 receives a fraction of the light from beam 23. For example, a relative vertical deflection of the cantilever (up or down with respect to the cantilevers equilibrium position) may be determined by obtaining a signal from the top half (T) of the detector 21 minus the signal from the bottom half (B) of the detector, i.e. the top-bottom signal (T-B signal).

If the probe tip 11 displaces or bends relative to the scan head 15 comprising the laser unit 20, the light spot formed on the optical detector 21 slightly displaces such that the ratio between the different areas illuminated by the light spot on each quadrant of the optical detector 21 changes. From this, the exact position and/or orientation of the probe tip 11 with respect to the scan head 15 can be determined. Because also the Z-position of the probe 10 as applied by the Z-actuator 18 is known (from the control data of the Z-actuator 18 or from a dedicated Z-sensor), the orientation and location of the probe tip 11 in the Z-direction can be determined. Furthermore, the XY position of the probe tip 11, indicating its position relative to the sample 7 within the plane of the substrate carrier 3, is known from the actuators of the substrate carrier 3 or corresponding sensors. In this manner, in each location of the XY plane, the exact orientation of the probe tip 11 in the Z-direction can be determined in combination with the Z-level applied via the Z-actuator 18 or dedicated Z-sensor. As an alternative to the OBD sensor system described above, a different sensor system may be applied in order to determine the position of the probe tip 11. For example, alternatively a piezoresistive sensor may be applied. The manner of applying a piezoresistive sensor in an SPM system 1 is not further described here.

In the system 1 illustrated in FIG. 3, the above information allows to very accurately determine the exact height of the surface 8 at each point in the XY plane. Therefore, the surface topography 9, consisting of a variety of different structures on the surface 8 of the sample 7, can be accurately determined and mapped such as to provide a topography map. In each point in the XY plane parallel to the sample surface 8, the exact Z-level of the surface 8 can be determined from the data provided for controlling the Z level actuator 18 and the data coming from the optical beam detector optical sensor 21 or from a dedicated Z-sensor. The data may for example be registered as three-dimensional measurement data in the memory 27 of the system 1. To provide a topography map of the 3D topography of the surface 8, in addition to the above analysis of the data of the Z-level actuator 18 or Z-sensor and the optical detector 21, a number of other processing steps have to be performed. These for example include noise reduction and the identification and removal of measurements artifacts.

Thus, in the SPM system 1, the location and orientation of probe tip 11 is obtained and registered by obtaining measurements with the OBD detector formed by laser unit 20 and optical detector 21 in combination with Z-level data obtained from the actuator control data of Z-level actuator 18 or Z-sensor. Furthermore, in the system 1, subsurface measurements are performed of any structures that may be below the surface 8 of sample 7. To this end, the substrate carrier 3 further includes a vibrational actuator that enables to apply a vibration 4 to the sample 7 from below. In alternative SPM systems, the vibrational signal 4 may be applied in different ways, for example by vibrational actuators on the surface 8 of the sample 7 or on the sides thereof. It is also possible to apply a vibrational signal via the probe 10 using vibrational transducers on the scan head 15, or via the probe tip 11 by periodic power intensity variations in the laser beam 23 provided by a laser unit 20. Such alternative manners of applying a vibrational signal 4 to the sample 7 have been described in literature and are not further discussed here. The present invention may be applied to measurements taken from SPM systems, such as the SPM system 1 performing surface topography measurements of topography 9 or performing subsurface measurements of structures below the top surface 8. The subsurface structure may for example be a preceding layer of a semiconductor element during manufacturing thereof, e.g. in order to detect whether the overlay of subsequent layers is sufficiently accurate to yield a fully functional semiconductor device, or whether the critical dimensions are as specified having the correct tolerances. In a method in accordance with the present invention, in some specific embodiments thereof, subsurface measurement is performed in order to further characterize sidewall structures that extend inward into a surface featured on surface 8. For example, subsurface measurements may enable to obtain information on a shape or depth of a sidewall recess.

In the system 1 of FIG. 3, the vibrational acoustic input signal applied via the substrate carrier 3 to the substrate 7 is picked up at the surface 8 of the sample 7 via the probe tip 11. Due to the vibrations, the Z-level of the probe tip 11 is periodically displaced at the frequency applied via the acoustic signal 4. Various of these acoustic measurements techniques are known in the art, amongst which for example the heterodyne methods that use a very high frequency gigahertz acoustic signal including two frequencies in the gigahertz range. The different frequency between two applied frequencies in the gigahertz range is relatively small, typically in the megahertz range. By using the principal of heterodyne mixing of signals, a low frequency signal at the difference frequency (in the megahertz range) can be picked up by the probe tip 11, and can be found by analysis of the output signal obtained via optical beam deflector unit 21. Again, this measurement data needs to be further analyzed in order to obtain therefrom the three dimensional topography data. For example amplitude and phase data may be obtained, and similar to the above, the identification of measurement artifacts and noise reduction is to be performed.

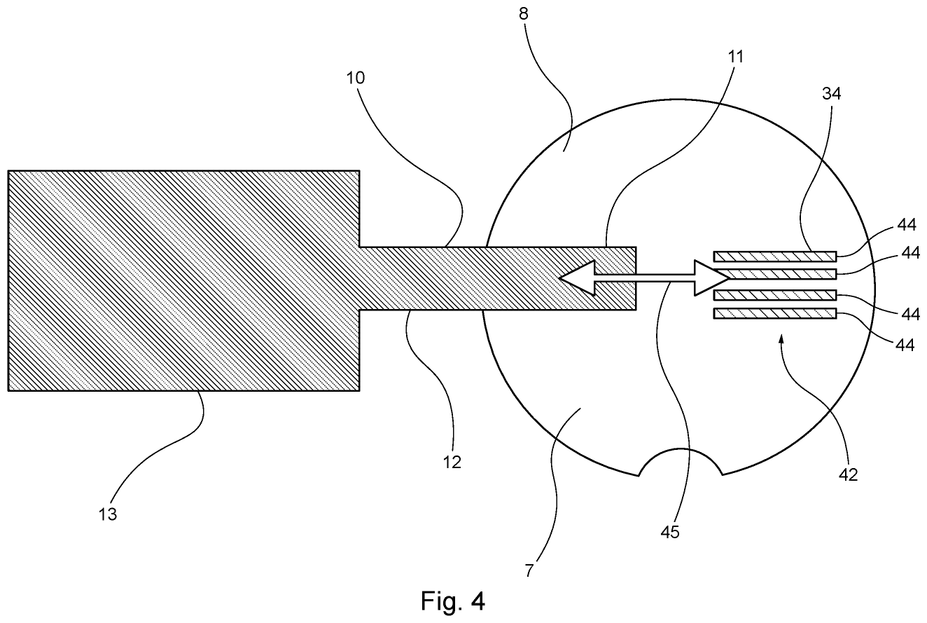

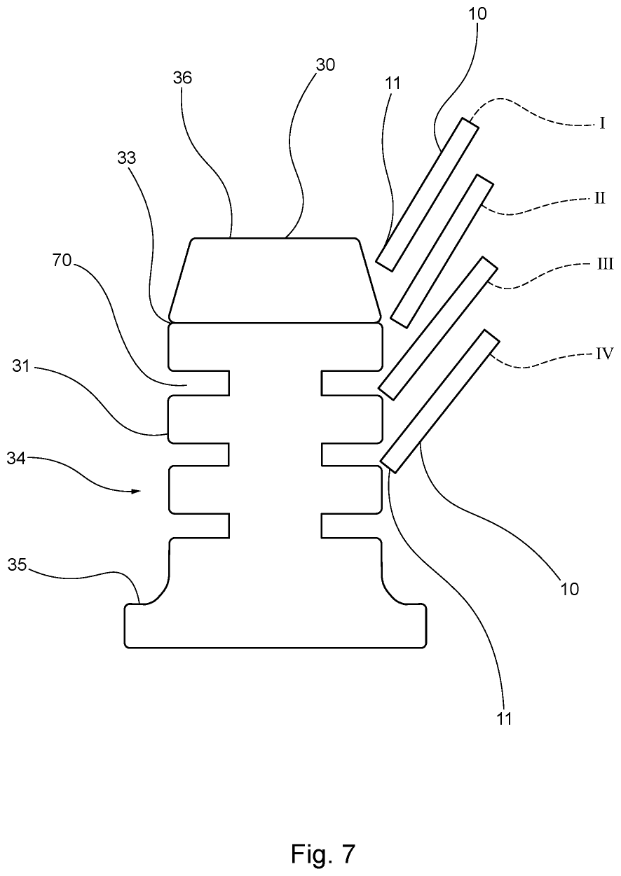

FIG. 4 schematically illustrates a probe chip 13 comprising a probe 10, including a cantilever 12 and probe tip 11. The figure also (very) schematically illustrates a substrate 7 having on its surface 8 a pattern 42 of fin structures 44 with side walls 34. The fin structures 44 are parallel to each other in a dense formation. Any source or drain structures 31, 31′ or 31″ (not visible in FIG. 4) extend from the side walls 34 of each fin 44. In order to perform a method in accordance with the present invention, the top-bottom signal (T-B signal) of the SPM can be analyzed in order to obtain the signal indicative of a grazing impact of the probe on the side wall 34. A grazing or sliding impact is the situation wherein the probe tip slides off the top 36 (e.g. see FIG. 7) of a fin with the probe tip 11 remaining in contact with the side wall 34. The capturing of a grazing impact signal is needed in order to be able to detect the location of any side lobes or other structures on the side wall 34. FIG. 4 illustrates an effective manner of obtaining such a signal. This manner is certainly not the only manner that may be applied in order to obtain a T-B signal indicative of grazing impact, but it is an effective method.

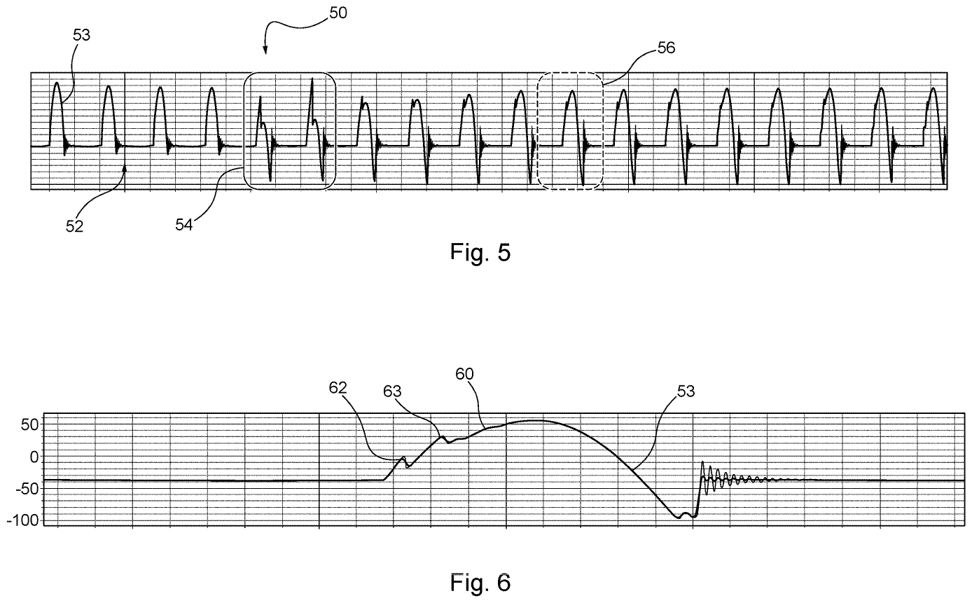

To obtain the T-B signal indicative of grazing impact, the probe 10 may be moved 45 in a relative direction parallel or just off-parallel to the direction of the fins 44 in periodic motion. This mode is characterized by a periodic motion of the probe 10 wherein, during each vibration, the probe tip 11 touches the surface 8 of the substrate 7. The probe tip 11 may be scanned in the direction of a fin 44 as illustrated in FIG. 4, whereas the graph 50 in FIG. 5 represents a T-B signal 53 obtained from the SPM system 1. While the probe tip 11 is above a fin 44 and touches the top surface 36 of the fin 44, a more or less standard output signal is obtained e.g. such as the first four cycles 52 of the signal 53. However, when the probe tip 11 starts to approach the edge of the surface 36 of the gate 30, typical transitional behavior 54 can be identified in the T-B signal 53. Thereafter, the probe tip 11 for a while will be in sliding impact or grazing impact, as characterized by the signal portion 56 of T-B signal 53.

FIG. 6 shows an enlargement of the signal portion 56 of T-B signal 53. The T-B signal on the upgoing flank thereof shows a number of local peaks 62 and 63. These peaks indicate the z-levels where the probe tip 11 encounters the various side lobes or side wall structures 31, 31′or 31″. This is illustrated with reference to FIG. 7.

FIG. 7 schematically illustrates a finFET in cross-section, including a gate 30 extending from a base 35 with side lobes 31 extending from side wall 34. Trenches 70 extend in between the side lobes 31. The gate 30 has a flat top surface 36, and an edge 33 extends between the gate 30 and side wall 34. FIG. 7 schematically shows the probe 10 in four positions I, II, III and IV on its way to the base 35 in a grazing motion past the side wall 34. The four positions I to IV correspond with various parts of the T-B signal in local maxima 62 and 63. For example, the flat section of signal 53 prior to peak 62 corresponds to the situation wherein the cantilever has no deflection while moving downward at position I. The deflection of cantilever 12 increases towards the edge 33 in position II, and quickly decreases in position III while encountering the valley 70. A same effect can be seen towards position IV, providing the local maximum 63. Thereafter, also a small maximum 60 can be distinguished while the probe moves further towards the base 35. Because at every position on T-B signal 53 the corresponding z-level is known (from the driver signal of the SPM that is driving the probe motion downwards or from a corresponding Z-sensor), it is possible to associate the various positions in each local maximum 62, 63 and 60 to a corresponding z-position of the probe tip 11. Furthermore, in case the dimensions of the probe tip 11 and its shape are known, potentially also the width of trenches 70 and their z-locations can be derived. This data is valuable during a manufacturing process, in order to enable verification of the correct manufacturing of the side lobes.

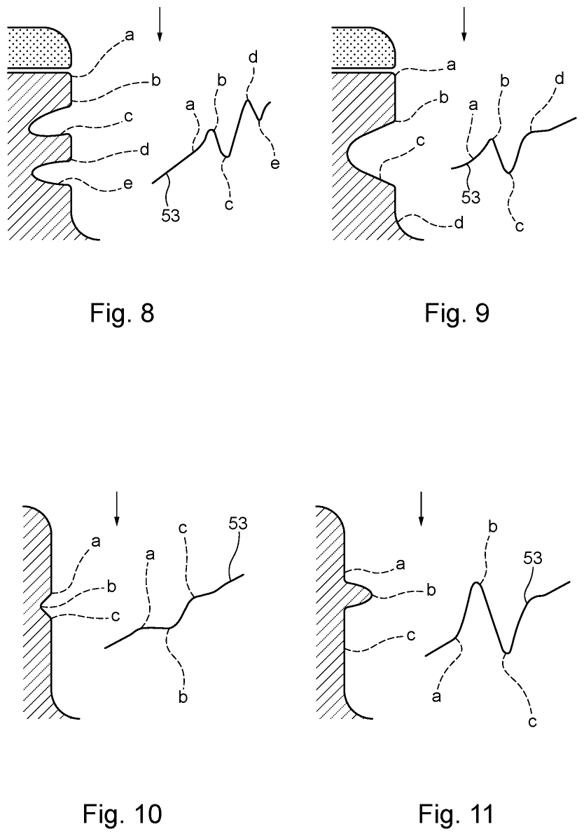

FIGS. 8, 9, 10 and 11 schematically illustrate various structures that may be present on a side wall 34, and how they may be detected in the T-B signal. For example, in FIG. 8 the situation with multiple side lobes is illustrated that we have also encountered in FIGS. 6 and 7. The positions a, b, c, d and e on the side wall have been indicated in schematic signal plot 53 to the right of the figure. The side lobes show up as several local maxima and minima on the flank of T-B signal 53.

FIG. 9 shows a side lobe with a broad and deep trench. From the onset of the local peak in T-B signal 53 at position a, the deflection increases towards position b, where it is at its maximum. Then, the deflection decreases again towards the bottom of the trench, to the onset of the next peak at position c. At position d, the probe tip comes out of the trench.

FIG. 10 shows the situation wherein a shallow and small trench is present on the side wall 34. At position a, the deflection starts to decrease towards the minimum at position b, and thereafter increases again until at position c the normal deflection signal is again obtained.

In FIG. 11, the situation of a sharp dimple on the side wall 34 is illustrated. Here, at position a, an increase in the deflection is detected. The deflection is at its maximum at position b. Thereafter, at position c, the deflection is at its minimum and from there moves back to its normal value.

The present invention has been described in terms of some specific embodiments thereof. It will be appreciated that the embodiments shown in the drawings and described herein are intended for illustrated purposes only and are not by any manner or means intended to be restrictive on the invention. It is believed that the operation and construction of the present invention will be apparent from the foregoing description and drawings appended thereto. It will be clear to the skilled person that the invention is not limited to any embodiment herein described and that modifications are possible which should be considered within the scope of the appended claims. Also kinematic inversions are considered inherently disclosed and to be within the scope of the invention. Moreover, any of the components and elements of the various embodiments disclosed may be combined or may be incorporated in other embodiments where considered necessary, desired or preferred, without departing from the scope of the invention as defined in the claims.

In the claims, any reference signs shall not be construed as limiting the claim. The term ‘comprising’ and ‘including’ when used in this description or the appended claims should not be construed in an exclusive or exhaustive sense but rather in an inclusive sense. Thus the expression ‘comprising’ as used herein does not exclude the presence of other elements or steps in addition to those listed in any claim. Expressions such as “consisting of”, when used in this description or the appended claims, should be construed not as an exhaustive enumeration but rather in an inclusive sense of “at least consisting of”. Furthermore, the words ‘a’ and ‘an’ shall not be construed as limited to ‘only one’, but instead are used to mean ‘at least one’, and do not exclude a plurality. Features that are not specifically or explicitly described or claimed may be additionally included in the structure of the invention within its scope. Any of the claimed or disclosed devices or portions thereof may be combined together or separated into further portions unless specifically stated otherwise, without departing from the claimed invention. Expressions such as: “means for . . . ” should be read as: “component configured for . . . ” or “member constructed to . . . ” and should be construed to include equivalents for the structures disclosed. The use of expressions like: “critical”, “preferred”, “especially preferred” etc. is not intended to limit the invention. Additions, deletions, and modifications within the purview of the skilled person may generally be made without departing from the spirit and scope of the invention, as is determined by the claims. The invention may be practiced otherwise then as specifically described herein, and is only limited by the appended claims.

1. A method of analyzing a probe tip deflection signal of a scanning probe microscopy system, for determining a location coordinate of a sidewall structure present on or in a sidewall of a surface feature, the surface feature being present on a surface of a substrate,
wherein the system comprises at least one probe head comprising a probe including a probe tip arranged on a cantilever, the probe head being configured for scanning the probe tip along one or more directions parallel to the substrate surface, the probe head comprising an actuator for applying a periodic motion to the probe tip during said scanning, and a tip position detector for providing a probe tip deflection signal indicative of a deviation of an actual position of the probe tip from a reference position along a z-direction transverse to the substrate surface, the method comprising:
obtaining, at a first scan position on the substrate surface, a first plurality of samples of the probe tip deflection signal over time at one or more positions of the probe tip along the z-direction during at least one first cycle of the periodic motion, for providing a signal profile at the first scan position using the first plurality of samples;
identifying the signal profile to be associated with a grazing impact of the probe tip on the sidewall;
detecting, in a slope of the signal profile which is associated with a probe tip motion in a z-direction towards the substrate surface, one or more variations in the slope, wherein the variations comprise local maxima or minima;
associating at least one of the variations with an interaction between the probe tip and the sidewall structure during the probe tip motion, and obtaining a z-position of the probe tip at the at least one variation; and
providing, as the location coordinate of the sidewall structure, the obtained z-position at the at least one variation.

2. The method according to claim 1, wherein the one or more variations relate to one or more of: ripples in the slope of the signal profile; and local extremes in the slope of the signal profile.

3. The method according to claim 1, wherein the step of identifying the signal profile to be associated with a grazing impact comprises at least one of:
providing the signal profile to a pattern recognition algorithm or pattern recognition data model for performing the identification; or
comparing the signal profile to one or more reference profiles.

4. The method according to claim 1, wherein the one or more sidewall structures include at least one of: a structure extending from the sidewall, or an opening or an indentation extending into the side wall.

5. The method according to claim 1, wherein the step of detecting one or more variations includes detecting a plurality of variations, and wherein the step of associating includes:
associating at least a first variation with an interaction between the probe tip and a first sidewall structure, associating at least a second variation with an interaction between the probe tip and a second sidewall structure, obtaining a first z-position of the probe tip at the first variation and obtaining a second z-position of the probe tip at the second variation, for associating the first and the second z-position with the first and the second sidewall structure.

6. The method according to claim 1, wherein the one or more sidewall structures include at least one opening or indentation extending into the side wall of the surface feature, wherein the method further comprises:
obtaining, at a second scan position and during at least one second cycle of the periodic motion, a second plurality of samples of the probe tip deflection signal over time, wherein the second scan position coincides with a top surface of the surface feature;
wherein during the second cycle, an acoustic signal is applied to at least one of the substrate or the probe tip to perform a subsurface feature detection measurement at the second scan position.

7. The method according to claim 6, wherein the method further comprises analyzing the second plurality of samples of the probe tip deflection signal to obtain measurement data indicative of a depth of the opening or indentation extending into the side wall.

8. The method according to claim 1, wherein the reference position is an equilibrium position, wherein the equilibrium position is a position which is in use assumed by the probe tip in absence of a force exerted thereon and in absence of the periodic motion.

9. The method according to claim 1, wherein the surface feature relates to a fin structure of a semiconductor element which is present on or is being formed on the surface, wherein the fin structure extends in a first direction along the substrate surface, wherein the method comprises a step of scanning the probe tip relative to the surface in a scanning direction, such that the scanning direction is parallel to the first direction.

10. A method of operating a scanning probe microscopy system to perform the method according to claim 1 of analyzing a probe tip deflection signal of a scanning probe microscopy system, for determining a location coordinate of a sidewall structure present on or in a sidewall of a surface feature, the surface feature being present on a surface of a substrate,
wherein the system comprises at least one probe head comprising a probe including a probe tip arranged on a cantilever, the probe head being configured for scanning the probe tip along one or more directions parallel to the substrate surface, the probe head comprising an actuator for applying a periodic motion to the probe tip during said scanning, and a tip position detector for providing a probe tip deflection signal indicative of a deviation of an actual position of the probe tip from a reference position along a z-direction transverse to the substrate surface,
wherein the scanning probe microscopy system further comprises a controller and a memory, the memory being configured for storing instructions which when loaded cause the controller to perform the steps of:
controlling the system to scan the probe tip relative to the substrate surface;
obtaining, at a first scan position on the substrate surface, a first plurality of samples of the probe tip deflection signal over time at one or more positions of the probe tip along the z-direction during at least one first cycle of the periodic motion, for providing a signal profile at the first scan position using the first plurality of samples;
identifying the signal profile to be associated with a grazing impact of the probe tip on the sidewall;
detecting, in a slope of the signal profile which is associated with a probe tip motion in a z-direction towards the substrate surface, one or more variations in the slope, wherein the variations comprise local maxima or minima; and
associating at least one of the variations with an interaction between the probe tip and the sidewall structure during the probe tip motion, and obtaining a z-position of the probe tip at the at least one variation;
providing, as the location coordinate of the sidewall structure, the obtained z-position at the at least one variation.

11. A non-transitory computer readable medium comprising a program of instructions which, when executed by a processor of a scanning probe microscopy system, execute the method according to claim 1.
